(19) United States
(12) Patent Application Publication
(10) Pub. No.: US 2025/0036850 A1
(43) Pub. Date: Jan. 30, 2025

(54) METHOD OF PREDICTING FAILURE IN A CIRCUIT DESIGN CAUSED BY NOISE IMPACT

(71) Applicant: INTERNATIONAL BUSINESS MACHINES CORPORATION, ARMONK, NY (US)

(72) Inventors: STEVEN JOSEPH KURTZ, AUSTIN, TX (US); DANIEL LEWIS, BANGALORE (IN); TUHIN MAHMUD, AUSTIN, TX (US); PIYUSHKUMAR BALDEVBHAI PATEL, GANDHINAGAR (IN); ALEXANDER JOEL SUESS, HOPEWELL JUNCTION, NY (US); GREGORY SCHAEFFER, POUGHKEEPSIE, NY (US); LARA CASSANDRA FLYNN, AUSTIN, TX (US); SYED FAZAL ABBAS, LUCKNOW (IN)

(21) Appl. No.: 18/361,532

(22) Filed: Jul. 28, 2023

(51) Int. Cl. G06F 30/398

(52) U.S. Cl. CPC G06F 30/398

(57) ABSTRACT

Predicting failure in a circuit design caused by noise impact including receiving, for a net representing the circuit design and including at least one of a source or a sink gate, data for a specified feature set; predicting a failure related to noise impact including induced switching of the net based on the data for the specified feature set and using noise tolerance information; upon receiving the prediction, modifying the net using the predicted failure information; and after modifying the net using the predicted failure information, re-predicting a failure related to noise impact including induced switching of the net based on updated data for the specified feature set and using noise tolerance information; and upon receiving the updated prediction, modifying the net using the updated predicted failure information.

### BACKGROUND

### Field of the Disclosure

The field of the disclosure is noise, or, more specifically, methods, apparatus, and products for predicting failure in a circuit design caused by noise impact.

### Description of Related Art

The development of the EDVAC computer system of 1948 is often cited as the beginning of the computer era. Since that time, computer systems have evolved into extremely complicated devices. Today's computers are much more sophisticated than early systems such as the EDVAC. Computer systems typically include a combination of hardware and software components, application programs, operating systems, processors, buses, memory, input/output devices, and so on. As advances in semiconductor processing and computer architecture push the performance of the computer higher and higher, more sophisticated computer software has evolved to take advantage of the higher performance of the hardware, resulting in computer systems today that are much more powerful than just a few years ago.

Typically, during chip design, neighboring wires can cause undesired effects upon each other. Switching of one wire induces current on neighboring wires which can alter signal switching times causing timing problems. Switching can also alter the voltage in non-switching neighbor wires and when the voltage changes too significantly, then the non-switching neighbor wire will incorrectly switch which destroys the data. This glitch is caused by noise impacting the chip and causing failure.

### SUMMARY

Methods, apparatuses, and products for predicting failure in a circuit design caused by noise impact according to various embodiments are disclosed. Predicting failure in a circuit design caused by noise impact can include: receiving, for a net representing the circuit design and including at least one of a source or a sink gate, data for a specified feature set; predicting a failure related to noise impact including induced switching of the net based on the data for the specified feature set and using noise tolerance information; and upon receiving the prediction, modifying the net using the predicted failure information. Predicting failure in a circuit design caused by noise impact can further include: after modifying the net using the predicted failure information, re-predicting a failure related to noise impact including induced switching of the net based on updated data for the specified feature set and using noise tolerance information; and upon receiving the updated prediction, modifying the net using the updated predicted failure information.

The foregoing and other objects, features and advantages of the disclosure will be apparent from the following more particular descriptions of exemplary embodiments of the disclosure as illustrated in the accompanying drawings wherein like reference numbers generally represent like parts of exemplary embodiments of the disclosure.

### BRIEF DESCRIPTION OF THE DRAWINGS

FIG. 1A is a block diagram of an example chip design used in predicting failure in a circuit design caused by noise impact in accordance with embodiments of the present disclosure.

FIG. 1B is a block diagram of an example chip design used in predicting failure in a circuit design caused by noise impact in accordance with embodiments of the present disclosure.

FIG. 1C is a block diagram of an example chip design used in predicting failure in a circuit design caused by noise impact in accordance with embodiments of the present disclosure.

FIG. 2 is an example of a graph used in predicting failure in a circuit design caused by noise impact according to some embodiments of the present disclosure.

FIG. 3A is an example of a table used in predicting failure in a circuit design caused by noise impact in accordance with embodiments of the present disclosure.

FIG. 3B is an example of a graph used in predicting failure in a circuit design caused by noise impact in accordance with embodiments of the present disclosure.

FIG. 4 is a block diagram of an example computing system configured for predicting failure in a circuit design caused by noise impact in accordance with embodiments of the present disclosure.

FIG. 5 is a flowchart of an example method for predicting failure in a circuit design caused by noise impact according to some embodiments of the present disclosure.

FIG. 6 is a flowchart of an example method for providing predicting failure in a circuit design caused by noise impact according to some embodiments of the present disclosure.

### DETAILED DESCRIPTION

During chip design, initial simulations use inputs and provide general layouts. As the chip design continues and becomes more mature, more details are added until a final simulation provides a complete picture of the chip design and layout with the highest accuracy and completeness including routing and timing information. At that point, noise interference and impact on the chip including induced switching on the chip and glitch becomes apparent, and failures caused by noise impact on the chip require modification, improvement, and correction. Predicting noise impact on the chip before the final simulation provides ease in improvement and is less disruptive to the chip design.

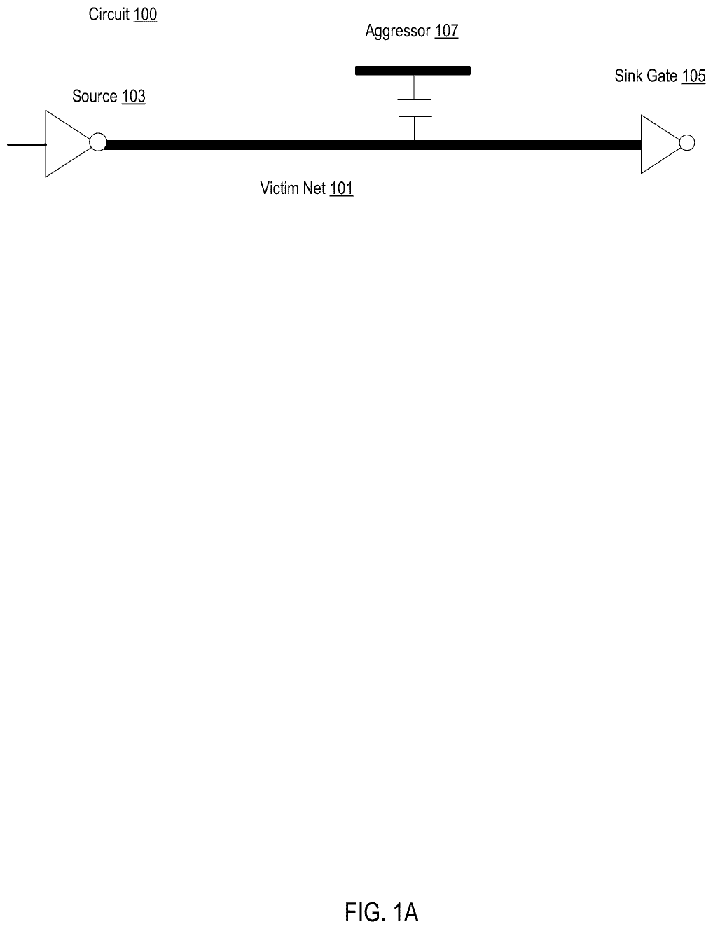

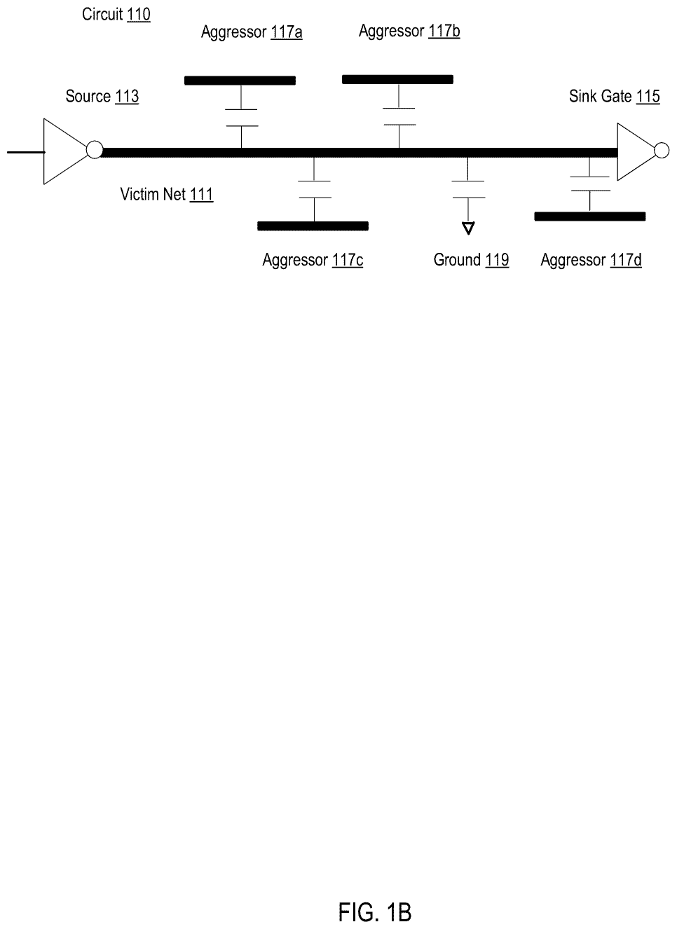

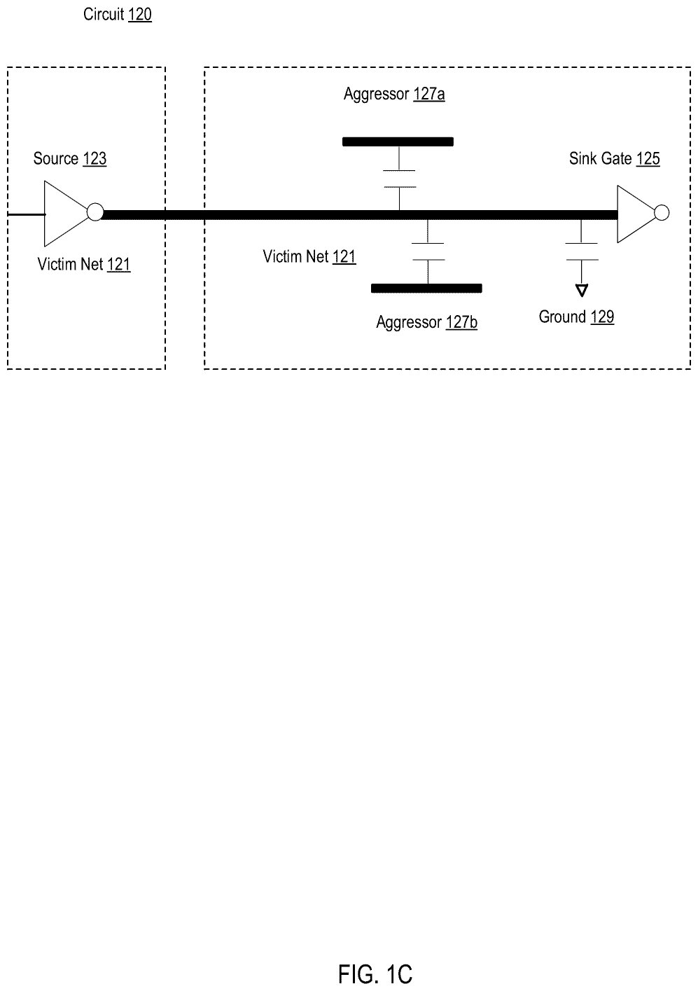

FIG. 1A sets forth a diagram of an exemplary portion of a circuit 100 illustrating noise impact on the net or circuit and a glitch induced switching on the net. In circuit 100, a victim net 101 includes a source 103 and a sink gate 105. In circuit 100, the source 103 is holding the victim net 101 at constant high logic, i.e., VDD, and the sink gate 105 receives the high voltage value. An aggressor 107 is capacitively coupled with the victim net 101. When the aggressor 107 switches, then the capacitive coupling between the nets causes a voltage change on the victim net 101. Thus, the switching of aggressor 107 causes the voltage of victim net 101 to drop relative to VDD, and when the voltage of victim net 101 drops too low, then its logical value will switch from high to low. The sink gate 105 then receives a low voltage value. Data has been incorrectly changed. If this data change is captured in a latch before the victim's driver can restore the victim wire to the correct voltage, then the information is destroyed.

FIG. 1B sets forth a diagram of another exemplary portion of a circuit 110 illustrating noise impact on the net or circuit and a glitch induced switching on the net. In circuit 110, a victim net 111 includes a source 113 with VDD and a sink gate 115. In circuit 110, the source 113 is at constant high logic, i.e., VDD, and the sink gate 115 receives the high voltage value. The victim net 110 is capacitively coupled to other neighboring wires that are not switching, and this capacitance is modeled as being connected to ground 119. Aggressors 117a, 117b, 117c, and 117d are capacitively coupled with the victim net 111 and when the aggressors 117a, 117b, 117c. and 117d switch, then the capacitive coupling between nets causes a voltage change on the victim net 111. Thus, the switching of aggressor nets 117a, 117b, 117c, and 117d causes the voltage of the victim net 111 to drop relative to VDD, and when the voltage of the victim net drops too low, then its logical value will switch from high to low. The sink gate 115 then receives a low voltage value. Data has been incorrectly changed and destroyed.

The switching shown in FIGS. 1A and 1B will drop the voltage of the victim net but not all switching by the aggressor net will cause the voltage of the victim net to drop too low and impact the net and destroy data. Some glitches are strong enough to drop the voltage of the victim net and switch a latch while others are within the noise margin and are safe. When the driver gate on the victim is a strong driver, meaning it provides a low resistance path to Ground or VDD, then the victim net effectively has a higher noise tolerance and when the driver gate on the victim is a weak driver, meaning it provides a high resistance path to Ground or VDD, then the victim net has a lower noise tolerance and is more susceptible to switching and failure. Some sink gates in some nets have a higher noise tolerance than others. Some general factors that affect noise include the proximity and number of aggressor nets, the amount of capacitive coupling to the aggressor net, and the drive strength of the victim net. Additional factors will be described hereinbelow.

FIG. 1C sets forth a diagram of another exemplary portion of a circuit 120 illustrating noise impact on the net or circuit and a glitch induced switching on the net. In circuit 120, a victim net 121 includes a source 123 with VDD and a sink gate 125. In circuit 120, the source 123 is at constant high logic and the sink gate 125 receives the high voltage value. The victim net 120 is capacitively coupled to other neighboring wires that are not switching, and this capacitance is modeled as being to ground 129. However, in circuit 120, not all of the information for the victim net 121 is known. Some parts of the victim net 121 are divided into different design blocks and evaluated separately. In FIG. 1C, the source 123 is in a separate design block of the victim net 121 and is evaluated with limited information about other parts of the victim net. Similarly, the sink gate 125 is in a separate design block of the victim net 121 and is evaluated with limited information about the portion of the circuit outside its own design block. Aggressors 127a, 127b are capacitively coupled with the victim net 121 and when the aggressors 127a, 127b switch, then the capacitive coupling between nets causes a voltage change on the victim net 121. Thus, the switching of aggressor nets 127a, 127b causes the voltage of the victim net 121 to drop relative to VDD, and when the voltage of the victim net drops too low, then its logical value will switch from high to low. The sink gate 125 then receives a low voltage value. Data has been incorrectly changed and destroyed. It should be understood that while the circuit 120 of FIG. 1C shows a source 123 and a sink gate 125, a net may include more than one sink gate, from two sink gates to many sink gates for a victim net. Information about one or more sink gates may be known and information about the source may be known or unknown.

Embodiments in accordance with the present disclosure provide a mechanism for predicting noise impact on the net or circuit at or before the final simulation during chip design. As the chip is designed, the physical design is optimized as well as verified and validated. During this optimization process, varying levels of detail concerning a wire's physical route, timing, parasitics, i.e., resistance and capacitance, is generated. This information can be used to simulate noise impact on the net or circuit. For each net, such as the exemplary nets described in FIGS. 1A, 1B, and 1C, a prediction for the noise impact on the net or circuit is made and when a failure is predicted, the net is modified and partially or fully corrected and improved. After improvement, a prediction is again made for the net and, when the net is predicted to pass, the optimization continues. This iterative process may happen many times before the net is predicted to pass.

Machine learning applications may perform various types of data analysis to automate analytical model building. Using algorithms that iteratively learn from data, machine learning applications can enable computers to learn without being explicitly programmed. Machine learning starts with training data that is cleaned or scrubbed, then used to select a feature set. Several models are selected, assessed, evaluated and tested. The chosen model is then fit, and trained in an iterative process.

Exemplary machine learning algorithms include classification and regression. Classification algorithms used in machine learning utilize input training data for the purpose of predicting the likelihood or probability that the data that follows will fall into one of the predetermined categories, i.e., pattern recognition. Classification algorithms applied to the training data find the same pattern in future data sets. Regression is the forecasting of continuous outcomes and generally involves plotting a line of best fit through the data points. Both are predictive modelling problems.

Possible feature sets to use in predicting failure caused by the noise impact on the chip include source strength, aggressor strength, noise tolerance of the net and the sink gate, length of wire, wire congestion, capacitance, timing, and others. Preferably selected feature sets can be used earlier in the chip design process, before the final design synthesis, allowing for failures to be corrected earlier in the design process.

Initially, training data is the dataset used to train machine learning algorithms and is generated using current and past chip designs. Training data is an essential component and uses quality, accurate, complete, and relevant data. As many variations as possible are gathered including data for source strength, aggressor strength, noise tolerance of the net and the sink gate, length of wire, wire congestion, capacitance, timing, and other data.

Data scrubbing or cleaning refers to identifying and correcting errors in the dataset that may negatively impact a predictive model. Data cleaning is the process of preparing data for analysis by removing or modifying data that is incorrect, incomplete, irrelevant, duplicated, or improperly formatted. The training data is scrubbed for use in the machine learning process. Issues with the dataset to be cleaned include imbalanced training sets with relatively few failures compared to the full data set and unpredictable failures that are filtered out from training.

Feature selection is the process of reducing the number of input variables when developing a predictive model. It is desirable to reduce the number of input variables to both reduce the computational cost of modeling and to improve the performance of the model. Feature selection methods are intended to reduce the number of input variables including redundant variables and irrelevant variables to those that are believed to be most useful to a model in order to predict the target variable.

Model selection is the process of selecting one final machine learning model from among a collection of candidate machine learning models for a training dataset. Model selection includes estimating the performance of different models in order to choose the best one. Model assessment includes, having chosen a final model, estimating its prediction error (generalization error) over an independent new data sample.

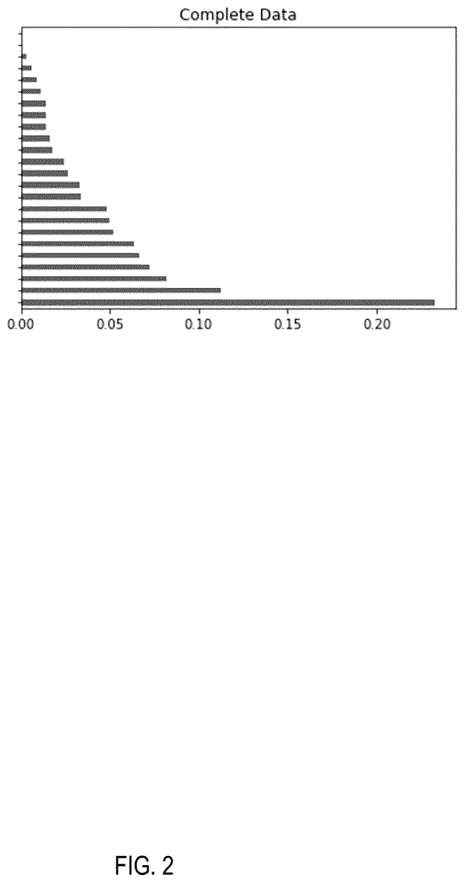

Classification models are used to evaluate features and their level of importance and to determine a feature set. FIG. 2 sets forth a graph of features on the y-axis and feature importance on the x-axis using a classification model. The most important features are the features with the highest importance at the bottom of the graph. Those features are selected for exemplary features to use and adjust during chip design to modify and correct predicted and actual failures caused by noise impact on the chip and glitches.

In an exemplary embodiment, using the dataset described above as input in machine learning algorithms including classification and regression algorithms, for large amounts of data, classifying features with high feature importance yields wire length and sink noise tolerance as exemplary features that can be used to modify and partially or fully correct predicted failures earlier in the chip design process than the final chip design simulation.

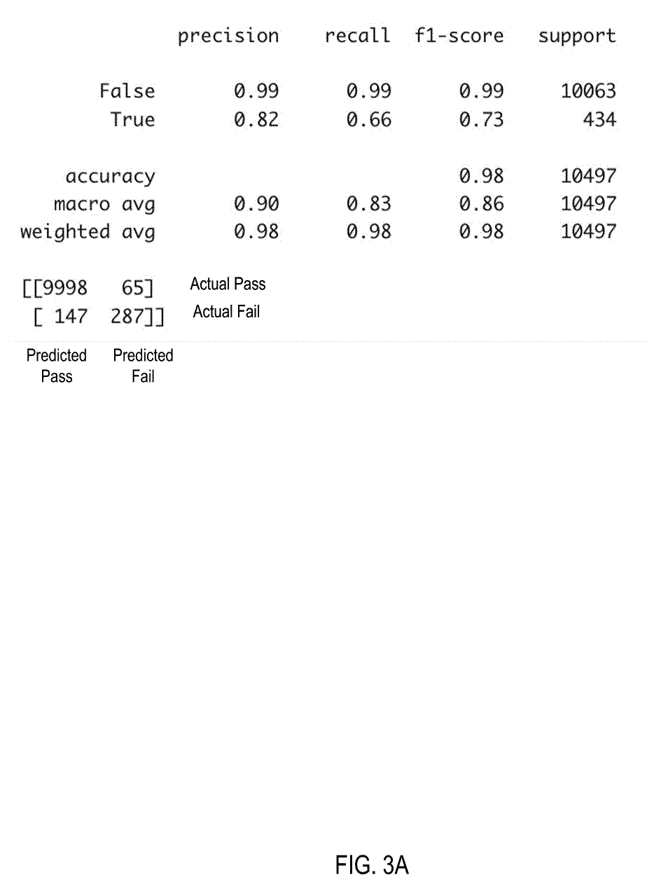

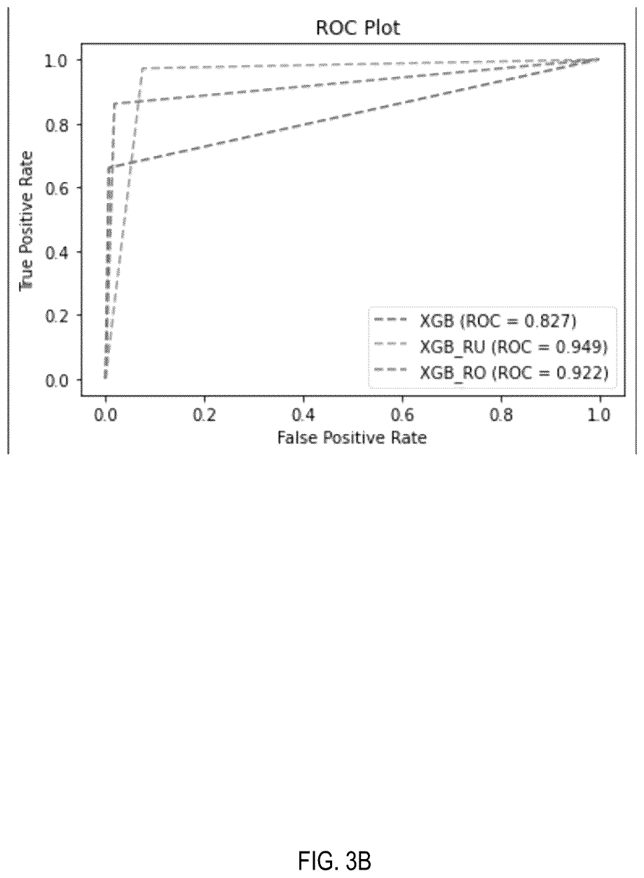

FIG. 3A sets forth results of model selection, assessment, and evaluation. In an exemplary embodiment, several models are used including XgBoost, Random Forest, and Adaboost. Using Random Undersampling for a training set, a model using XgBoost predicts 66% of primary input fail nets while only mispredicting 1% of passing nets. FIG. 3B sets forth the area under ROC which determines the performance of the algorithm, with a higher value showing better performance.

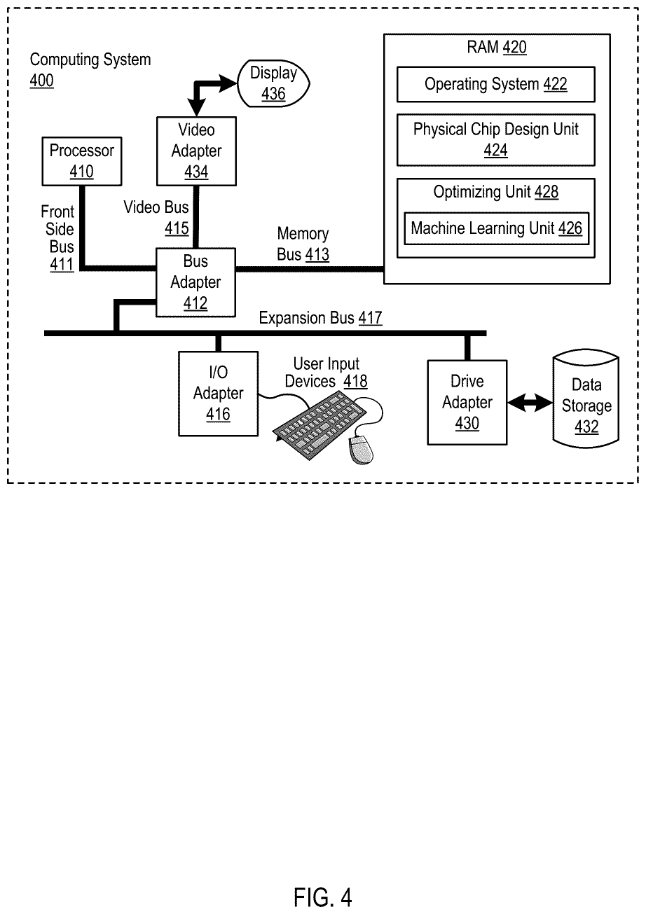

Exemplary apparatus and systems for predicting failure in a circuit design caused by noise impact in accordance with the present disclosure are described with reference to the accompanying drawings, beginning with FIG. 4. FIG. 4 sets forth a block diagram of automated computing machinery comprising an exemplary computing system 400 configured for predicting failure in a circuit design caused by noise impact according to embodiments of the present disclosure. The computing system 400 of FIG. 4 includes at least one computer processor 410 or ‘CPU’ as well as random access memory (‘RAM’) 420 which is connected through a high-speed memory bus 413 and bus adapter 412 to processor 410 and to other components of the computing system 400.

Stored in RAM 420 is an operating system 422. Operating systems useful in computers configured for predicting failure in a circuit design caused by noise impact according to embodiments of the present disclosure include z/OS™, UNIX™, Linux™, Microsoft Windows™, AIX™, and others as will occur to those of skill in the art. The operating system 422 in the example of FIG. 4 is shown in RAM 420, but many components of such software typically are stored in non-volatile memory also, such as, for example, on data storage 432, such as a disk drive.

Also stored in RAM is a physical chip design unit 424. The physical chip design unit 424 designs the physical design layout of the chip, including placement, routing, connections, and timing. The physical chip design unit 424 is used in a process with many steps with initial placement and additional details being added and determined until the final design is complete. The physical chip design unit 424 also determines violations and failures.

Also stored in RAM is the machine learning unit 426. The machine learning unit 426 receives data, including timing and routing information from the PDS 424 and performs machine learning on the data to predict pass and failure. The machine learning unit 426 in an exemplary embodiment uses XgBoost to determine a pass/fail classification or a probabilistic determination of the noise slack in the net and a likelihood of failure. Noise slack is a measure of how the simulated noise pulse on a wire compare to the noise tolerance of a sink gate or pin. Noise slack includes a relative measure of how the noise pulse observed at a sink gate compares to the maximum amount of noise that the sink gate is capable of handling without switching and may be indicated with a measurement in mV or other units.

Also stored in RAM is an optimizing unit 428. The optimizing unit 428 is embodied in a set of processor-executable instructions that, when executed by the processor 410, causes the computing system 400 to carry out the steps of receiving, for a net representing the circuit design and including at least one of a source or a sink gate, data for a specified feature set; predicting a failure related to noise impact including induced switching on the net based on the data for the specified feature set and using noise tolerance information; upon receiving the prediction, modifying the net using the predicted failure information; and after modifying the net using the predicted failure information, re-predicting a failure related to noise impact including induced switching on the net based on the updated data for the specified feature set and using noise tolerance information; and upon receiving the updated prediction, modifying the net using the updated predicted failure information.

The computing system 400 of FIG. 4 includes disk drive adapter 430 coupled through expansion bus 417 and bus adapter 412 to processor 410 and other components of the computing system 400. Disk drive adapter 430 connects non-volatile data storage to the computing system 400 in the form of data storage 432. Disk drive adapters useful in computers configured for predicting glitch failure caused by noise impact on the net, circuit, or chip according to embodiments of the present disclosure include Integrated Drive Electronics (‘IDE’) adapters, Small Computer System Interface (‘SCSI’) adapters, and others as will occur to those of skill in the art. Non-volatile computer memory also may be implemented for as an optical disk drive, electrically erasable programmable read-only memory (so-called ‘EEPROM’ or ‘Flash’ memory), RAM drives, and so on, as will occur to those of skill in the art.

The example computing system 400 of FIG. 4 includes one or more input/output (‘I/O’) adapters 416. I/O adapters implement user-oriented input/output through, for example, software drivers and computer hardware for controlling output to display devices such as computer display screens, as well as user input from user input devices 418 such as keyboards and mice. The example computing system 400 of FIG. 4 includes a video adapter 434, which is an example of an I/O adapter specially designed for graphic output to a display device 436 such as a display screen or computer monitor. Video adapter 434 is connected to processor 410 through a high speed video bus 415, bus adapter 412, and the front side bus 411, which is also a high speed bus.

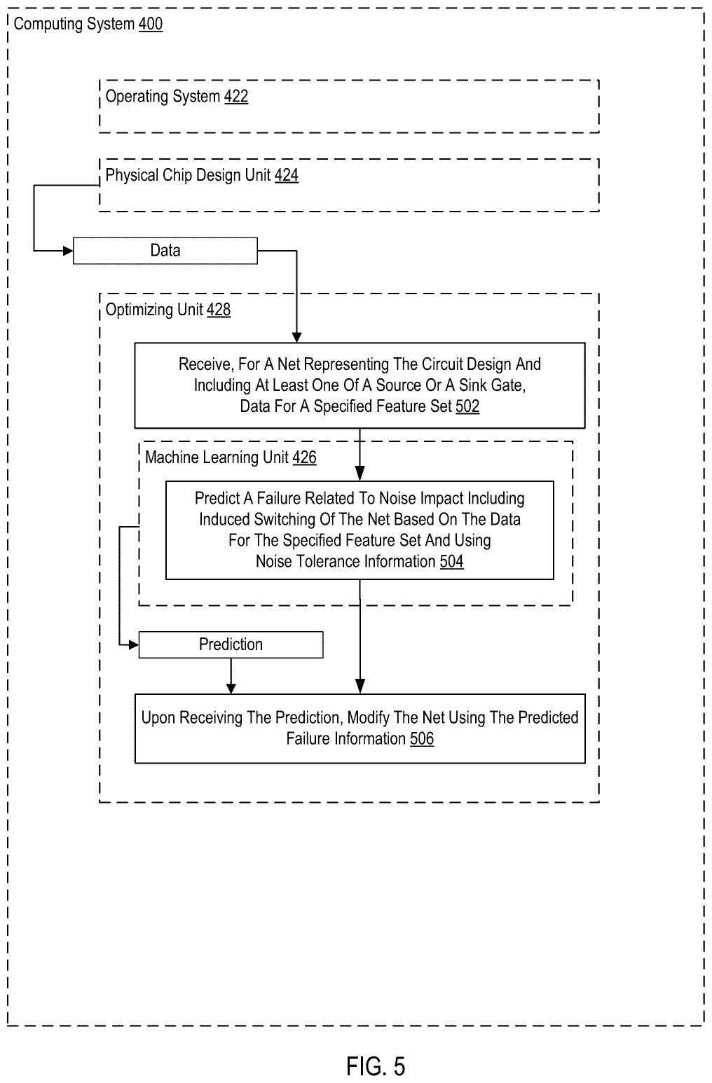

For further reference, FIG. 5 sets forth a flow chart of example method of predicting failure in a circuit design caused by noise impact in accordance with some embodiments of the present disclosure. The method of FIG. 5 includes receiving 502, for a net representing the circuit design and including at least one of a source or a sink gate, data for a specified features set. Receiving 502, for a net representing the circuit design and including at least one of a source or a sink gate, data for a specified features set includes the optimizing unit 428 of FIG. 4 receiving net information from the physical chip design unit 424, including timing and routing information at a point in the design process prior to the final chip design. In an exemplary embodiment, the data for the net includes wire length and noise tolerance. Noise tolerance includes noise tolerance information for the sink gate that is determined from previous detailed simulations of the behavior of the gate when subjected to a range of different noise pulses. In some examples, the net is victim net 101, the source is source 103, and the sink gate is sink gate 105 of FIG. 1A or the net is victim net 111, the source is source 113, and the sink gate is sink gate 115 of FIG. 1B. In some examples, the net is victim net 121 and the source and sink gate is either source 123 or sink gate 125 of FIG. 1C.

The method of FIG. 5 also includes predicting 504 a failure related to noise impact including induced switching on the net based on the data for the specified feature set and using noise tolerance information. Predicting 504 a failure related to noise impact including induced switching on the net based on the data for the specified feature set and using noise tolerance information includes the machine learning unit 426 using the net information to generate a prediction for the net. In some examples, the machine learning algorithms may be classification or regression models or other machine learning models as is known in the art. The machine learning algorithms may be a general model or a primary input specific model. In an exemplary embodiment, XgBoost predicts 66% of primary input fail nets while only mispredicting 1% of passing nets. In some embodiments, the machine learning unit 426 generates a pass/fail prediction for the net. In some embodiments, the machine learning unit 426 generates a noise slack prediction, which includes a relative measure of how the noise pulse observed at a sink gate compares to the maximum amount of noise that the sink gate is capable of handling without switching.

The method of FIG. 5 also includes upon receiving the prediction, modifying 506 the net using the predicted failure information. In some examples, modifying 506 the net using the predicted failure information includes the optimizing unit 428 modifying 506 the net using the predicted failure information by changing the chip layout by inserting a buffer, changing the source gate or sink gate, moving placement, or rerouting wires, as is known in the art. The modification improves the chip layout and partially or fully corrects the failure.

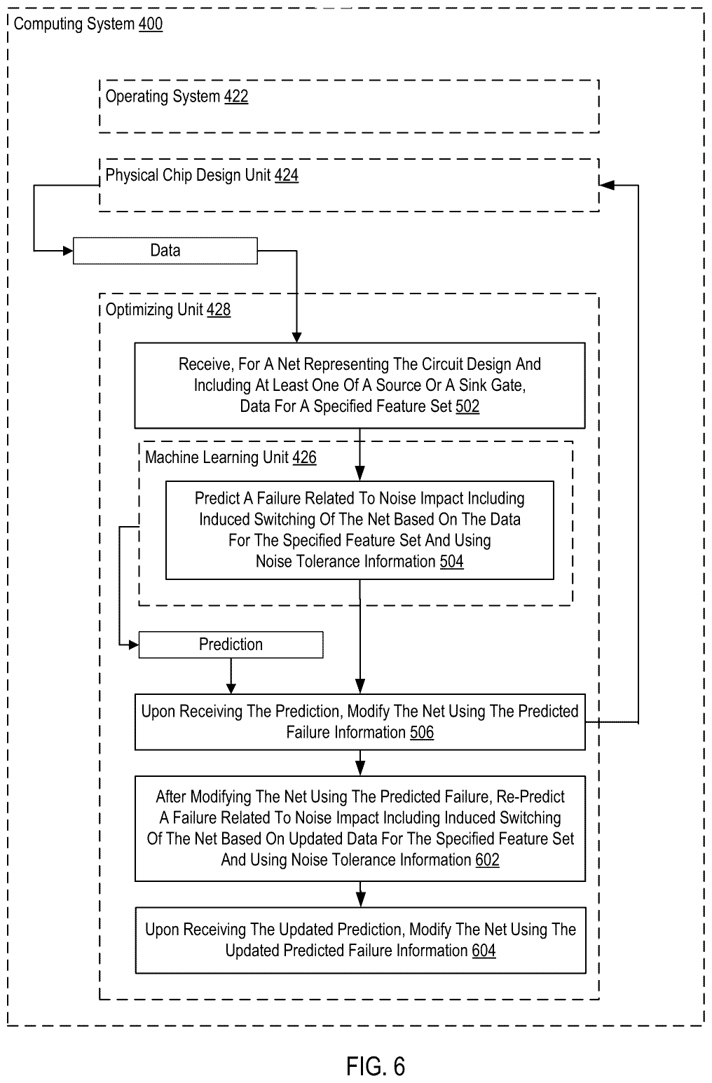

For further explanation, FIG. 6 sets forth a flow chart of example method of predicting failure in a circuit design caused by noise impact according to some embodiments of the present disclosure. The example method depicted in FIG. 6 is similar to the example method depicted in FIG. 5, as the example method in FIG. 6 also includes receiving 502, for a net representing the circuit design and including at least one of a source or a sink gate, data for a specified features set; predicting 504 a failure related to noise impact including induced switching on the net based on the data for the specified feature set and using noise tolerance information; and upon receiving the prediction, modifying 506 the net using the predicted failure information.

The method of FIG. 6 differs from FIG. 5 in that the method of FIG. 6 also includes after modifying the net using the predicted failure information, re-predicting 602 a failure related to noise impact including induced switching on the net based on the updated data for the specified feature set and using noise tolerance information. After modifying the net using the predicted failure information, re-predicting 602 a failure related to noise impact including induced switching on the net based on the updated data for the specified feature set and using noise tolerance information includes the machine learning unit 426 using the net information to generate a prediction for the net. The updated net information is used, similarly to the prediction described above, by the machine learning unit 426 to generate a prediction for the net. As described above, the machine learning algorithms may be classification or regression models or other machine learning models as is known in the art. The machine learning algorithms may be a general model or a primary input specific model. In an exemplary embodiment, XgBoost predicts 66% of primary input fail nets while only mispredicting 1% of passing nets. In some embodiments, the machine learning unit 426 generates a pass/fail prediction for the net. In some embodiments, the machine learning unit 426 generates a noise slack prediction, which includes a relative measure of how the noise pulse observed at a sink gate compares to a maximum amount of noise that the sink gate is capable of handling without switching.

The method of FIG. 6 further differs from FIG. 5 in that the method of FIG. 6 also includes upon receiving the updated prediction, modifying 604 the net using the updated predicted failure information. Upon receiving the updated prediction, modifying 604 the net using the updated predicted failure information includes the optimizing unit 428 modifying 604 the net using the updated predicted failure information. The modification improves the chip layout and partially or fully corrects the failure.

In an iterative process, an updated prediction of failure for the net may then be modified by the optimizing unit 428 modifying the net to improve the chip layout and partially or fully correct the failure. Modifying the net using the updated prediction of failure for the net may be by changing the chip layout by inserting a buffer, changing the source gate or sink gate, moving placement, or rerouting wires, as is known in the art. The iterative process of predicting. modifying, predicting using updated data, modifying, again predicting using updated data, again modifying, and so on, may be repeated additionally and as many times as needed or as practical, such as 5, 10, 25 times or more. A single prediction and modification may correct the failure or a number of iterations of prediction and modification may be performed. A limit of number of times may be selected, based upon timing or computing constraints.

Additionally, the iterative process of FIGS. 5 and 6 can be automated by the optimizing unit 428 using selected pass/fail parameters and modification parameters or using selected noise slack thresholds and modification parameters, as well as selected iteration thresholds.

In view of the explanations set forth above, readers will recognize a number of advantages of predicting failure in a circuit design caused by noise impact according to embodiments of the present disclosure including:
Predicting failure in a circuit design caused by noise impact on the net, circuit, or chip.
Predicting and improving nets susceptible to failure caused by noise impact on the net. circuit, or chip prior to detailed sign-off analysis.
Automating noise impact on net, circuit, or chip avoidance based on prediction.
Leveraging source and sink gate noise related features like driver strength and sink noise tolerance to help predict noise tolerance.

Exemplary embodiments of the present disclosure are described largely in the context of a fully functional computer system for predicting failure in a circuit design caused by noise impact. Readers of skill in the art will recognize, however, that the present disclosure also may be embodied in a computer program product disposed upon computer readable storage media for use with any suitable data processing system. Such computer readable storage media may be any storage medium for machine-readable information, including magnetic media, optical media, or other suitable media. Examples of such media include magnetic disks in hard drives or diskettes, compact disks for optical drives, magnetic tape, and others as will occur to those of skill in the art. Persons skilled in the art will immediately recognize that any computer system having suitable programming means will be capable of executing the steps of the method of the disclosure as embodied in a computer program product. Persons skilled in the art will recognize also that, although some of the exemplary embodiments described in this specification are oriented to software installed and executing on computer hardware, nevertheless, alternative embodiments implemented as firmware or as hardware are well within the scope of the present disclosure.

The present invention may be a system, a method, and/or a computer program product. The computer program product may include a computer readable storage medium (or media) having computer readable program instructions thereon for causing a processor to carry out aspects of the present invention.

The computer readable storage medium can be a tangible device that can retain and store instructions for use by an instruction execution device. The computer readable storage medium may be, for example, but is not limited to, an electronic storage device, a magnetic storage device, an optical storage device, an electromagnetic storage device, a semiconductor storage device, or any suitable combination of the foregoing. A non-exhaustive list of more specific examples of the computer readable storage medium includes the following: a portable computer diskette, a hard disk, a random access memory (RAM), a read-only memory (ROM), an erasable programmable read-only memory (EPROM or Flash memory), a static random access memory (SRAM), a portable compact disc read-only memory (CD-ROM), a digital versatile disk (DVD), a memory stick, a floppy disk, a mechanically encoded device such as punch-cards or raised structures in a groove having instructions recorded thereon, and any suitable combination of the foregoing. A computer readable storage medium, as used herein, is not to be construed as being transitory signals per se, such as radio waves or other freely propagating electromagnetic waves, electromagnetic waves propagating through a waveguide or other transmission media (e.g., light pulses passing through a fiber-optic cable), or electrical signals transmitted through a wire.

Computer readable program instructions described herein can be downloaded to respective computing/processing devices from a computer readable storage medium or to an external computer or external storage device via a network, for example, the Internet, a local area network, a wide area network and/or a wireless network. The network may comprise copper transmission cables, optical transmission fibers, wireless transmission, routers, firewalls, switches, gateway computers and/or edge servers. A network adapter card or network interface in each computing/processing device receives computer readable program instructions from the network and forwards the computer readable program instructions for storage in a computer readable storage medium within the respective computing/processing device.

Computer readable program instructions for carrying out operations of the present invention may be assembler instructions, instruction-set-architecture (ISA) instructions, machine instructions, machine dependent instructions, microcode, firmware instructions, state-setting data, or either source code or object code written in any combination of one or more programming languages, including an object oriented programming language such as Smalltalk, C++ or the like, and conventional procedural programming languages, such as the “C” programming language or similar programming languages. The computer readable program instructions may execute entirely on the user's computer, partly on the user's computer, as a stand-alone software package, partly on the user's computer and partly on a remote computer or entirely on the remote computer or server. In the latter scenario, the remote computer may be connected to the user's computer through any type of network, including a local area network (LAN) or a wide area network (WAN), or the connection may be made to an external computer (for example, through the Internet using an Internet Service Provider). In some embodiments, electronic circuitry including, for example, programmable logic circuitry, field-programmable gate arrays (FPGA), or programmable logic arrays (PLA) may execute the computer readable program instructions by utilizing state information of the computer readable program instructions to personalize the electronic circuitry, in order to perform aspects of the present invention.

Aspects of the present invention are described herein with reference to flowchart illustrations and/or block diagrams of methods, apparatus (systems), and computer program products according to embodiments of the invention. It will be understood that each block of the flowchart illustrations and/or block diagrams, and combinations of blocks in the flowchart illustrations and/or block diagrams, can be implemented by computer readable program instructions.

These computer readable program instructions may be provided to a processor of a general purpose computer, special purpose computer, or other programmable data processing apparatus to produce a machine, such that the instructions, which execute via the processor of the computer or other programmable data processing apparatus, create means for implementing the functions/acts specified in the flowchart and/or block diagram block or blocks. These computer readable program instructions may also be stored in a computer readable storage medium that can direct a computer, a programmable data processing apparatus, and/or other devices to function in a particular manner, such that the computer readable storage medium having instructions stored therein comprises an article of manufacture including instructions which implement aspects of the function/act specified in the flowchart and/or block diagram block or blocks.

The computer readable program instructions may also be loaded onto a computer, other programmable data processing apparatus, or other device to cause a series of operational steps to be performed on the computer, other programmable apparatus or other device to produce a computer implemented process, such that the instructions which execute on the computer, other programmable apparatus, or other device implement the functions/acts specified in the flowchart and/or block diagram block or blocks.

The flowchart and block diagrams in the Figures illustrate the architecture, functionality, and operation of possible implementations of systems, methods, and computer program products according to various embodiments of the present invention. In this regard, each block in the flowchart or block diagrams may represent a module, segment, or portion of instructions, which comprises one or more executable instructions for implementing the specified logical function(s). In some alternative implementations, the functions noted in the block may occur out of the order noted in the figures. For example, two blocks shown in succession may, in fact, be executed substantially concurrently, or the blocks may sometimes be executed in the reverse order, depending upon the functionality involved. It will also be noted that each block of the block diagrams and/or flowchart illustration, and combinations of blocks in the block diagrams and/or flowchart illustration, can be implemented by special purpose hardware-based systems that perform the specified functions or acts or carry out combinations of special purpose hardware and computer instructions.

It will be understood from the foregoing description that modifications and changes may be made in various embodiments of the present disclosure without departing from its true spirit. The descriptions in this specification are for purposes of illustration only and are not to be construed in a limiting sense. The scope of the present disclosure is limited only by the language of the following claims.

What is claimed is:

1. A method for predicting failure in a circuit design caused by noise impact, the method comprising:
receiving, for a net representing the circuit design and including at least one of a source or a sink gate, data for a specified feature set;
predicting a failure related to noise impact including induced switching of the net based on the data for the specified feature set and using noise tolerance information; and
upon receiving the prediction, modifying the net using the predicted failure information.

2. The method of claim 1 further comprising:
after modifying the net using the predicted failure information, re-predicting a failure related to noise impact including induced switching of the net based on updated data for the specified feature set and using noise tolerance information;
upon receiving the updated prediction, modifying the net using the updated predicted failure information.

3. The method of claim 1 wherein modifying the net using the predicted failure information comprises:
inserting a buffer.

4. The method of claim 1 wherein the noise tolerance information comprises sink gate noise tolerance information.

5. The method of claim 1 wherein the prediction is a pass/fail prediction.

6. The method of claim 1 wherein the prediction is an amount of noise slack.

7. An apparatus for predicting failure in a circuit design caused by noise impact, the apparatus comprising a computer processor, a computer memory operatively coupled to the computer processor, the computer memory having disposed within it computer program instructions that, when executed by the computer processor, cause the apparatus to carry out the steps of:
receiving, for a net representing the circuit design and including at least one of a source or a sink gate, data for a specified feature set;
predicting a failure related to noise impact including induced switching of the net based on the data for the specified feature set and using noise tolerance information; and
upon receiving the prediction, modifying the net using the predicted failure information.

8. The apparatus of claim 7, further comprising:
after modifying the net using the predicted failure information, re-predicting a failure related to noise impact including induced switching of the net based on updated data for the specified feature set and using noise tolerance information; and
upon receiving the updated prediction, modifying the net using the updated predicted failure information.

9. The apparatus of claim 8, wherein modifying the net using the predicted failure information comprises:
inserting a buffer.

10. The apparatus of claim 7, wherein the noise tolerance information comprises sink gate noise tolerance information.

11. The apparatus of claim 7 wherein the prediction is a pass/fail prediction.

12. The apparatus of claim 7 wherein the prediction is an amount of noise slack.

13. A computer program product for predicting failure in a circuit design caused by noise impact, the computer program product disposed upon a computer readable medium, the computer program product comprising computer program instructions that, when executed, cause a computer to carry out the steps of:
receiving, for a net representing the circuit design and including at least one of a source or a sink gate, data for a specified feature set;
predicting a failure related to noise impact including induced switching of the net based on the data for the specified feature set and using noise tolerance information; and
upon receiving the prediction, modifying the net using the predicted failure information.

14. The computer program product of claim 13 further comprising:
after modifying the net using the predicted failure information, re-predicting a failure related to noise impact including induced switching of the net based on updated data for the specified feature set and using noise tolerance information; and
upon receiving the updated prediction, modifying the net using the updated predicted failure information.

15. The computer program product of claim 14 wherein modifying the predicted failure comprises:
inserting a buffer.

16. The computer program product of claim 13 wherein the noise tolerance information comprises sink gate noise tolerance information.

17. The computer program product of claim 13 wherein the prediction is a pass/fail prediction.

18. The computer program product of claim 13 wherein the prediction is an amount of noise slack.

19. The computer program product of claim 13 wherein the computer readable medium comprises a storage medium.
